(19) United States
(12) Patent Application Publication
(10) Pub. No.: US 2009/0219181 A1
(43) Pub. Date: Sep. 3, 2009

(54) METHOD AND DEVICE FOR TRANSMITTING AND RECEIVING SIGNALS

(75) Inventors: Bin LI, Shenzhen (CN); Yi LUO, Shenzhen (CN)

Correspondence Address: Leydig, Voit & Mayer, Ltd;(for Huawei Technologies Co., Ltd), Two Prudential Plaza Suite 4900, 180 North Stetson Avenue, Chicago, IL, 60601, US

(73) Assignee: HUAWEI TECHNOLOGIES CO., LTD., Shenzhen (CN)

(21) Appl. No.: 12/399,424

(22) Filed: Mar. 6, 2009

Related U.S. Application Data
(63) Continuation of application No. PCT/CN2007/070248, filed on Jul. 6, 2007.

(30) Foreign Application Priority Data
Sep. 8, 2006 (CN) 200610152000.9

(51) Int. Cl. H03M 7/20

(52) U.S. Cl. 341/102

(57) ABSTRACT

The present invention relates to the field of wireless communications and discloses wireless signal transmission and reception methods and devices, thus more information can be transmitted via a fixed resource block. In the present invention, at the transmitter side, information for transmission is divided into an n-bit part and an m-bit part, the n-bit part being taken as information borne in a physical resource and a corresponding mapping mode is selected in accordance with the m-bit part; at the receiver side, a sequence carrying a received signal is de-mapped according to all possible mapping modes of the received signal and transmitted information is derived from an optimum signal sequence resulting from de-mapping and corresponding mapping mode.

### CROSS-REFERENCE TO RELATED APPLICATIONS

This application is a continuation of International Patent Application No. PCT/CN2007/070248, filed Jul. 6, 2007, which claims priority to Chinese Patent Application No. 200610152000.9, filed Sep. 8, 2006, both of which are hereby incorporated by reference in their entirety.

### FIELD OF THE INVENTION

The present invention relates to the field of wireless communications, and in particular to a method and device for transmitting and receiving wireless signals.

### BACKGROUND OF THE INVENTION

With the rapid development of sciences and technologies, development of mobile communication technologies has been gaining more and more attention. A communication system utilizing a spread spectrum technology has played an important role among mobile communication technologies which develop continuously.

A Walsh code is one of orthogonal spread spectrum codes typically used in the communication system utilizing the spread spectrum technology. The Walsh code can eliminate or suppress Multi Access Interference (MAI). Also the Walsh code can be used for transmitting an information sequence. For example, a 10-bit information sequence can be mapped into a 1024-bit Walsh code, and the receiver side correlates the received information sequence with 1024 Walsh codes to thereby recover the information by detecting the maximum correlation peak due to orthogonality of Walsh codes. Information sequences belonging to different terminals and different channels are mapped into Walsh codes which are in turn scrambled differently in order to multiplex the same physical resource for the different terminals and the different channels. This approach is very suitable for transmitting short control commands to multiple terminals over a resource (time, frequency and space) with a known location so as to reduce a control channel overhead.

A reason for this lies in that information sequences are mapped into Walsh codes which are scrambled differently for different channels and different terminals and then superposed, and at this time, signals transmitted from the different channels and the different terminals can be processed as interferences with each other. Therefore no resource assignment information needs to be transmitted for information transport over a fixed resource (or a variable resource with a known location to a terminal from its variation regularity) to thereby reduce an overhead of control information transmission on the condition of guaranteeing controlled channel performance.

The feature of Walsh codes is commonly utilized in current wireless communication systems to transmit information such as control information, signaling, etc. Similar to the spectrum spread, this approach maps N-bit information or signaling directly into a Walsh code of 2^{N} bits, which is then scrambled to distinguish between terminals and channels. Scrambling is also intended to randomize interference of the signal in question to another signal to thereby facilitate reception of other signals. Such a system can map N-bit information or signaling into a Walsh code or another orthogonal sequence, as illustrated in FIG. 1.

The receiver side firstly descrambles the received signal and then correlates it with respective 2^{N}-bit Walsh sequences, as illustrated in FIG. 2. In the case that the receiver side performs coherent detection, values obtained from coherent detection are correlated with respective 2^{N}-bit Walsh sequences to find N-bit information corresponding to the maximum correlation peak as an output of the received information sequence.

An explanation will be presented below, taking an Orthogonal Frequency Division Multiplexing (OFDM) in the 802.20 standard of the Institute of Electrical and Electronics Engineers (IEEE) as an example.

As illustrated in FIG. 3, control information transmitted over respective control channels may not necessarily be identical in frame length, and typically, the frame length is 10 bits or less. The control information of less than 10 bits can be padded with zeros up to 10 bits for transmission. For example, 5-bit information of a Channel Quality Indicator (CQI) channel is padded with zeros into a 10-bit information sequence which is then HADAMARD mapped (i.e., selecting a row or column from a 1024×1024 HADAMARD orthogonal matrix) into a 1024-bit Walsh code, as illustrated in FIG. 4. Alternatively, after 5-bit information is mapped into a 32-bit Walsh code, a 1024-bit sequence can be obtained by repetition, as illustrated in FIG. 5. Thereafter, the 1024-bit sequence is scrambled differently for different channels to distinguish one channel from another. The Walsh codes scrambled for the different channels are combined additively into 1024 bits which are then scrambled with another scrambling code to distinguish different cells or sectors. The 1024 bits are divided into 8 sub-blocks and each sub-block contains 128 bits which are subject to 128-point Fast Fourier Transform (FFT) to output 128 complex values, and the 1024 complex values are carried over consecutive 128 sub-carriers and 8 symbols in the OFDM system.

The receiver side is structured as illustrated in FIG. 6. The signals which have experienced channel fading are firstly subject to FFT through the OFDM reception system and then 128-point Inverse Discrete Fourier Transform (IDFT), which are respective inverse processes of Inverse Fast Fourier Transform (IFFT) and 128-point Discrete Fourier Transform (DFT) of the OFDM system in the transmitter, and thereafter are descrambled and correlated respectively. Each of 1204 correlation peaks resulting from correlation of the 1024-bit Walsh sequence corresponds to 10-bit information. The information corresponding to the maximum correlation peak is taken as an output.

In the conventional art, the amount of resources (including time, frequency or space resources) occupied by the system during transmission of control information will increase exponentially as the length N of transmitted information increases. By way of an example, an orthogonal code mapped will increase in length from of 2^{N} bits to 2^{N+1} bits as the information length increases from N bits to N+1 bits. The amount of resources needs to be increased when the length of information exceeds what can be borne in a resource block, thus resulting in a considerable overhead of resources for transmission of the information due to the exponential relation between addition of resources and the length of the transmitted information in bits.

### SUMMARY OF THE INVENTION

Accordingly, embodiments of the invention provide a method and device for transmitting and receiving wireless signals, so as to transmit more information in a resource block.

An embodiment of the invention provides a signal transmission method, including (1) dividing information for transmission into an n-bit part and an m-bit part, the n-bit part being taken as information borne in a physical resource; and (2) mapping a sequence carrying the n-bit part with a mapping mode corresponding to the m-bit part and then transmitting the sequence.

An embodiment of the invention provides a signal reception method, including (1) de-mapping a sequence carrying a received signal with all possible mapping modes of the received signal; and (2) deriving transmitted information from an optimum signal sequence resulting from de-mapping and corresponding mapping mode.

An embodiment of the invention provides a signal transmission device, including (1) a division module, adapted to divide information for transmission into an n-bit part and an m-bit part, the n-bit part being taken as information borne in a physical resource; (2) a mapping selection module, adapted to select a corresponding mapping mode in accordance with the m-bit part; and (3) a mapping module, adapted to map a sequence carrying the n-bit part with a mapping mode corresponding to the m-bit part and then transmit the sequence.

An embodiment of the invention provides a signal reception device, including (1) a de-mapping module, adapted to de-map a sequence carrying a received signal according to all possible mapping modes of the received signal; and (2) an information recovery module, adapted to derive transmitted information from an optimum signal sequence resulting from de-mapping and corresponding mapping mode.

In the embodiments of the invention, information for transmission is divided into an m-bit part and an n-bit part at the transmitter side. The n-bit part is taken as information borne in a physical resource. The m-bit part is used as a basis for selection of a mapping mode, and the information borne in the physical resource is mapped with the selected mapping mode and then transmitted. The receiver side de-maps the received signal with all possible mapping modes of the transmitter side, and derives the information for transmission of the transmitter side from the optimum signal sequence resulting from de-mapping and corresponding mapping mode. Thus, more information can be transmitted in a fixed resource block to thereby improve a utilization ratio of the resource significantly without degrading performance of the system.

### BRIEF DESCRIPTION OF THE DRAWINGS

FIG. 1 is a schematic diagram of conventional information transmission utilizing the feature of Walsh codes;

FIG. 2 is a schematic diagram of conventional information reception utilizing the feature of Walsh codes;

FIG. 3 is a schematic diagram of conventional signal transmission of an OFDM system;

FIG. 4 is a schematic diagram of the conventional mapping of a signal of less than 10 bits for transmission into a 1024-bit sequence;

FIG. 5 is a schematic diagram of the conventional extension of a signal of less than 10 bits for transmission by duplication thereof into a 1024-bit sequence;

FIG. 6 is a schematic diagram of conventional signal reception over a single antenna of an OFDM system;

FIG. 7 is a flow chart of a signal transmission method according to a first embodiment of the invention;

FIG. 8 is a schematic diagram of the signal transmission method according to the first embodiment of the invention;

FIG. 9 is a flow chart of a signal reception method according to a second embodiment of the invention;

FIG. 10 is a schematic diagram of the signal reception method according to the second embodiment of the invention;

FIG. 11 is a schematic diagram of a signal reception method according to a third embodiment of the invention;

FIG. 12 is a schematic diagram of a signal transmission method according to a fourth embodiment of the invention;

FIG. 13 is a schematic diagram of a signal reception method according to a fifth embodiment of the invention;

FIG. 14 is a schematic diagram of a signal reception method according to a sixth embodiment of the invention;

FIG. 15 is a schematic diagram of a signal transmission method according to a seventh embodiment of the invention;

FIG. 16 is a schematic diagram of a signal coherent reception method corresponding to the seventh embodiment of the invention;

FIG. 17 is a schematic diagram of a signal transmission method according to an eighth embodiment of the invention;

FIG. 18 is a schematic diagram of a signal coherent reception method corresponding to the eighth embodiment of the invention;

FIG. 19 is a schematic diagram of a signal transmission method according to a ninth embodiment of the invention;

FIG. 20 is a schematic diagram of a signal transmission method according to a tenth embodiment of the invention;

FIG. 21 is a schematic diagram of a signal reception method according to an eleventh embodiment of the invention;

FIG. 22 is a schematic diagram of a signal transmission method according to a twelfth embodiment of the invention;

FIG. 23 is a schematic diagram of a signal reception method according to a thirteenth embodiment of the invention;

FIG. 24 is a schematic diagram of a structure of a signal transmission device according to a fourteenth embodiment of the invention;

FIG. 25 is a schematic diagram of a structure of a signal reception device according to a fifteenth embodiment of the invention;

FIG. 26 is a schematic diagram of a structure of a signal transmission device according to a sixteenth embodiment of the invention;

FIG. 27 is a schematic diagram of a structure of a signal transmission device according to an eighteenth embodiment of the invention; and

FIG. 28 is a schematic diagram of a structure of a signal reception device according to a nineteenth embodiment of the invention.

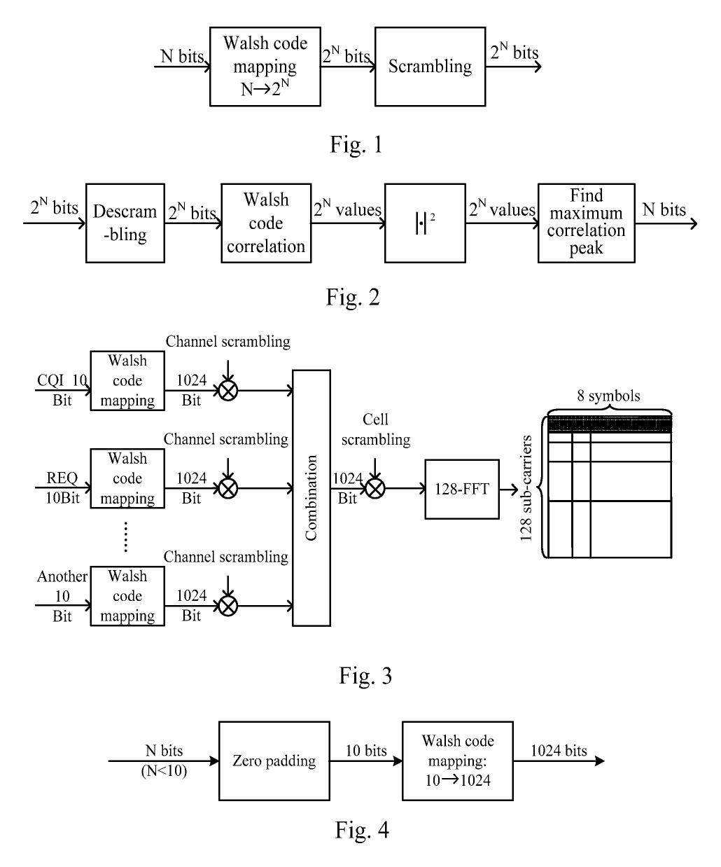

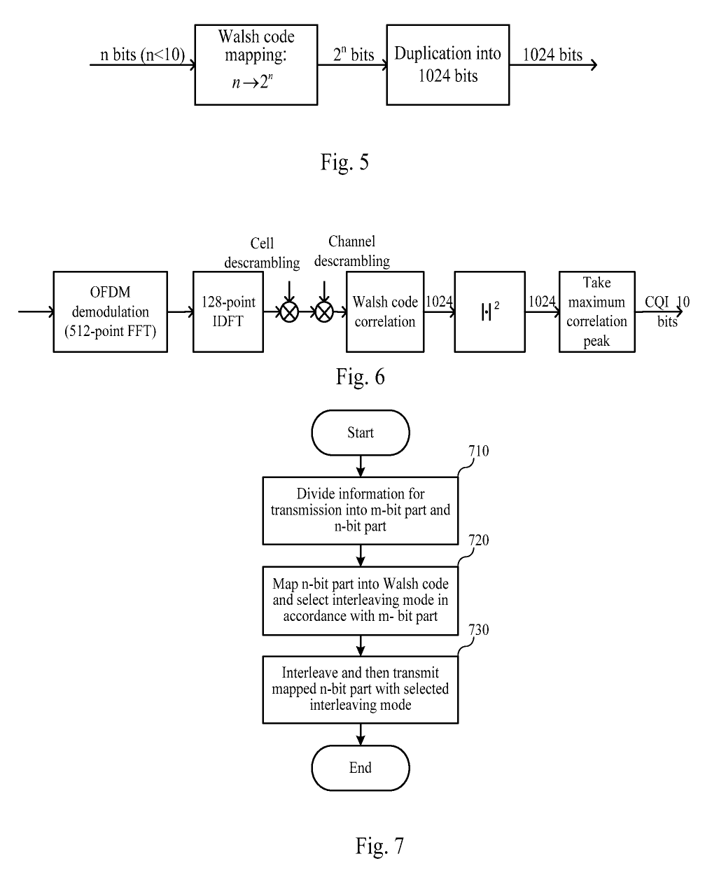

### DETAILED DESCRIPTION OF THE EMBODIMENTS

The invention will be further detailed below with reference to the drawings to make the objects, aspects and advantages of the invention more apparent.

In embodiments of the invention, at the transmitter side, k-bit information over a channel is decomposed into n-bit information for transmission as information borne in a physical resource and m-bit information for selecting a different information mapping mode and then mapping the n-bit information or a transmission sequence derived from the n-bit information into a transmission sequence over the channel according to the selected information mapping mode. The information mapping mode includes interleaving, scrambling or another user-selected mapping mode dependent upon a specific application scenario, all of which can randomize interference of the channel to another channel. The n-bit information can also be encoded in a user-selected mode as required for a specific application, for example, the n-bit information can be mapped into a Walsh code.

At the receiver side, the received signal is de-mapped according to each possible information mapping mode of the transmitter side. Part of the information for transmission of the transmitter side is derived from the optimum signal sequence, and the remaining part of the information for transmission of the transmitter side is derived from the mapping mode corresponding to the optimum signal sequence. The de-mapping mode and the mode of deriving the optimum sequence, which are adopted at the receiver side, correspond to the information mapping mode and the encoding mode at the transmitter side.

In the OFDM signal transmission system as illustrated in FIG. 3, a transmission sequence over a channel can be derived with a transmission method or a transmission device according to an embodiment of the invention. The transmission sequence over the channel can be scrambled over the channel and combined with a transmission sequence scrambled over another channel or can be combined directly with a signal scrambled over another channel without being scrambled. At the receiver side, a process corresponding to that at the transmitter side is needed to derive information transmitted over a channel

A first embodiment of the invention will be set forth in details below. The first embodiment of the invention relates to a signal transmission method, a specific flow of which is as illustrated in FIG. 7.

In the step 710, the transmitter side divides information for transmission into an m-bit part and an n-bit part. Specifically, it is assumed that the information for transmission over a control channel is of 10 bits and only 8-bit information can be borne in a fixed resource block for bearing transmission information. Therefore, in order to transmit the 10-bit information via a fixed resource block, the 10-bit information is segmented into m-bit information and n-bit information, which are 2-bit information and 8-bit information respectively, and the 8-bit information is taken as information borne in a physical resource block.

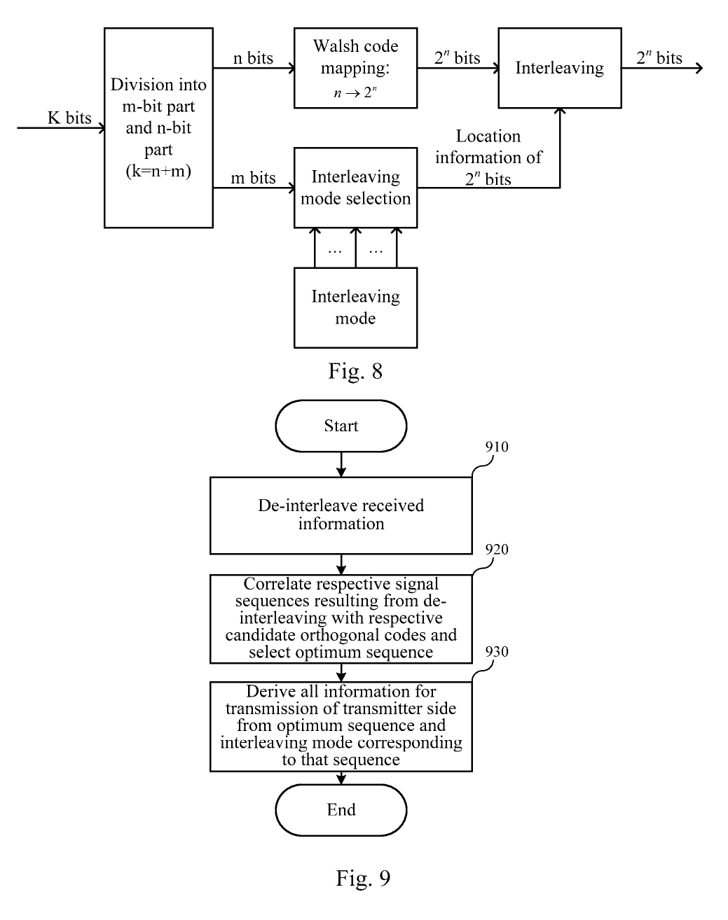

Next the flow proceeds to step 720 where the transmitter side encodes the n-bit part, for example, by mapping it into a Walsh code or another orthogonal code, and selects an interleaving mode in accordance with the m-bit part. Specifically, the n-bit part is mapped into a 2ⁿ-bit Walsh code sequence, and a corresponding interleaving mode is selected from 2^{m} interleaving modes in accordance with the m-bit part, as illustrated in FIG. 8. For the above example, the 8-bit information resulting from segmentation is mapped into a 2⁸-bit Walsh code sequence, and a corresponding interleaving mode is selected from 2² interleaving modes in accordance with the 2-bit information.

Next the flow proceeds to step 730 where the transmitter side interleaves the Walsh code into which the n-bit part is mapped according to the selected interleaving mode and transmits a transmission sequence resulting from interleaving. For the above example, the transmitter side interleaves the mapped 2⁸-bit Walsh code sequence according to the interleaving mode corresponding to the 2-bit information and transmits a 2⁸-bit signal sequence resulting from interleaving. Since the interleaving can disturb the order of a transmission information sequence, a transmission sequence in a spread spectrum-like communication system is typically a Walsh code or another orthogonal code having a feature that the number of bits 0 equals to or approximate equals to the number of bits 1. Therefore, interference of a transmission signal of such an information sequence to another signal can be randomized by interleaving.

For a system in which a high information transmission rate is required, a Doppler frequency shift occurs over a channel at a high movement rate, and the channel varies rapidly and makes a feature of a rapidly and constantly changing angular spread. Therefore, when a transmission sequence for transmission requires a long time, the Doppler frequency shift is caused easily. In this embodiment, long information is segmented into an m-bit part and an n-bit part, the n-bit part is taken as information borne in a physical resource and the m-bit is transmitted by selecting an interleaving mode. For example, 10-bit information is segmented into 2-bit part and 8-bit part, the 8-bit part can be transmitted in a physical resource block and the 2-bit part can be transmitted by selecting an interleaving mode, so that the 10-bit information can be transmitted in a fixed resource block. As compared with an increased number of resource blocks for transmitting more information in the conventional art, this embodiment can reduce the time for transmission of a sequence and thus reduce an influence due to the Doppler frequency shift. Therefore, this embodiment can be applicable to a system in which high performance is required over a channel at a high movement rate. Furthermore, a signal for transmission can be interleaved to randomize its interference to another signal to thereby distinguish users while achieving a temporal diversity gain. Also as compared with the conventional art, more information can be transmitted in a fixed resource block to thereby improve a utilization ratio of the resource significantly without degrading performance of the system.

A second embodiment of the invention relates to a signal reception method for receiving the signal transmitted in the first embodiment, a specific flow of which is as illustrated in FIG. 9.

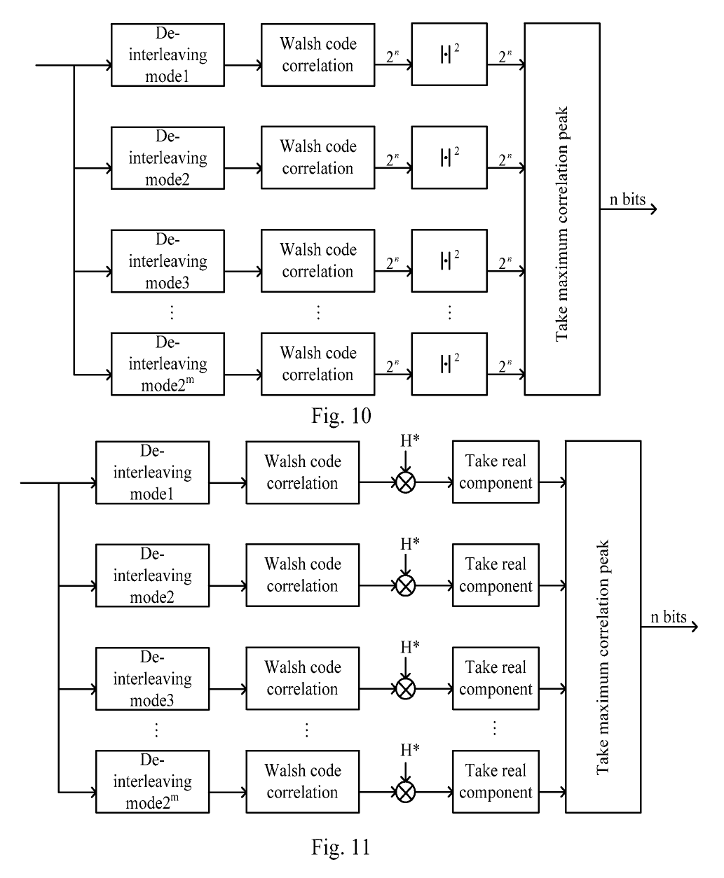

In step 910, the receiver side de-interleaves the received signal. Specifically, since the transmitter side may interleave the transmission information borne in the physical resource with any of the 2^{m} interleaving modes, the receiver side needs to de-interleave the received signal in each possible interleaving mode of the transmitter side, that is, de-interleave the received signal with 2^{m} de-interleaving modes, as illustrated in FIG. 10.

Next the flow proceeds to step 920 where the receiver side correlates respective signal sequences resulting from de-interleaving with respective candidate orthogonal codes and selects the optimum signal sequence there from by correlation results. Specifically, since the receiver side de-interleaves the received signal with the respective 2^{m} de-interleaving modes, the total number of the signal sequences resulting from de-interleaving is 2^{m} and the signal sequences are correlated with the respective candidate orthogonal codes. Since the n-bit transmission information borne in the physical resource is mapped into a 2ⁿ-bit orthogonal code (e.g., Walsh code), the total number of the candidate orthogonal codes is 2ⁿ. That is, each de-interleaving mode corresponds to 2ⁿ correlation peaks, and therefore respective correlations of the 2^{m} signal sequences with the respective candidate orthogonal codes result in correlation peaks, the total number of which is 2^{m}*2ⁿ. The maximum correlation peak is taken from the 2^{m}*2ⁿ correlation peaks, and the n-bit information corresponding to the maximum correlation peak is the optimum signal sequence, as illustrated in FIG. 10.

Next the flow proceeds to step 930 where the receiver side derives all the information for transmission of the transmitter side in accordance with the optimum signal sequence and the interleaving mode corresponding to the optimum signal sequence. Specifically, the receiver side derives the optimum signal sequence in accordance with the maximum correlation peak taken from the 2^{m}*2ⁿ correlation peaks, and this signal sequence is the transmission information borne in the physical resource at the transmitter side, i.e., the n-bit part. Since the transmitter side transmits the remaining part of the information for transmission with the interleaving mode of the transmission information borne in the physical resource, the receiver side can know the interleaving mode of the transmission information borne in the physical resource and further know the remaining part of the information for transmission at the transmitter side, i.e., the m-bit part, only according to the de-interleaving mode corresponding to the optimum signal sequence. To this end, the receiver side obtains all the information for transmission at the transmitter side.

Compared with a system in which information is put into different resource blocks for transmission and part of the information for transmission at the transmitter side is indicated with selected resource block, this embodiment does not need to search different resource blocks. Thus, the complexity of the system is reduced significantly.

A third embodiment of the invention relates to a signal reception method for receiving the signal transmitted in the first embodiment and is substantially the same as the second embodiment except that the second embodiment adopts non-coherent detection and this embodiment adopts coherent detection.

Specifically, as illustrated in FIG. 11, the receiver side derives a channel parameter H from a pilot signal, processes values of the 2^{m}*2ⁿ correlation peaks by the conjugation H* of the channel parameter H, and selects the n-bit information corresponding to the maximum correlation peak as an output, and the n-bit information is the optimum sequence. Both the process that the 2^{m}*2ⁿ correlation peaks is processed with H and the process that the maximum correlation peak is derived can employ the coherent detection in the conventional art.

A fourth embodiment of the invention relates to a signal transmission method and is substantially the same as the first embodiment except that the transmitter side selects one of the 2^{m} interleaving modes in accordance with the m-bit part and interleaves and transmits an orthogonal code into which the n-bit part is mapped according to the selected interleaving mode in the first embodiment; and the transmitter side selects one of 2^{m} scrambling modes in accordance with the m-bit part and scrambles and transmits the orthogonal code into which the n-bit part is mapped according to the selected scrambling mode in this embodiment.

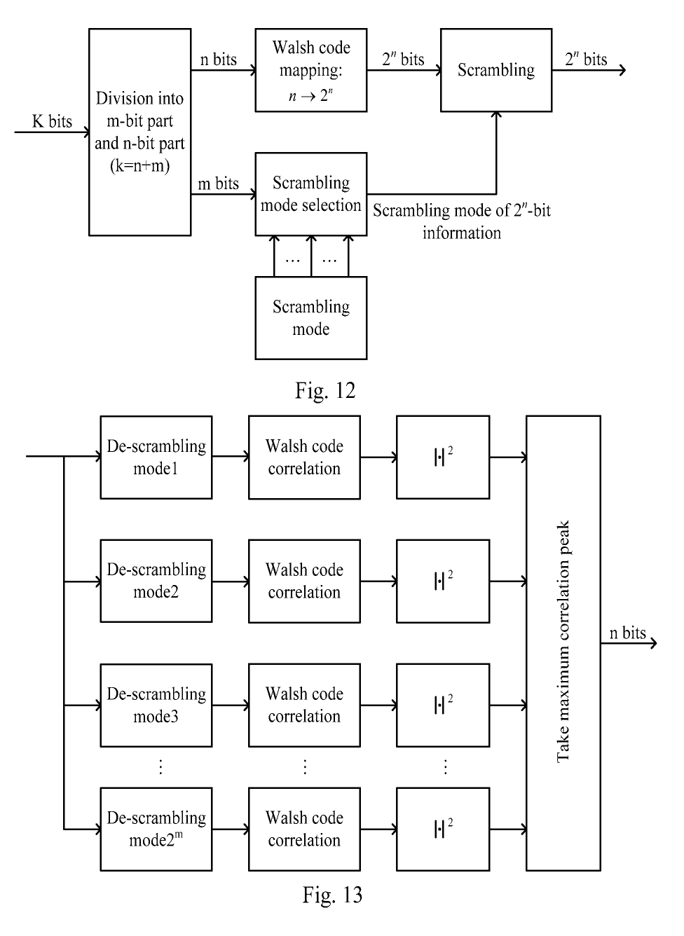

Specifically, as illustrated in FIG. 12, the transmitter side divides k-bit information for transmission into an m-bit part and an n-bit part, maps the n-bit part into an orthogonal code, e.g., a Walsh code, and selects corresponding scrambling mode from 2^{m} scrambling modes in accordance with the m-bit part, where different m-bit information corresponds to different scrambling modes. The transmitter side scrambles and then transmits the orthogonal code into which the n-bit part is mapped according to the selected scrambling mode.

As can be readily apparent in this embodiment, long information is also segmented into an m-bit part and an n-bit part, the n-bit part is taken as information borne in a physical resource, and the m-bit part is transmitted with a selected scrambling mode, for example, 10-bit information is segmented into 2-bit part and 8-bit part, the 8-bit part can be transmitted in a physical resource block, and the 2-bit part is transmitted with a selected scrambling mode, so that the 10-bit information can be transmitted with one fixed resource block. As compared with an increased number of resource blocks for transmitting more information in the conventional art, this embodiment can enable a physical resource block transmit more information for transmission to thereby improve greatly a utilization ratio of the resource without degrading performance of the system.

A fifth embodiment of the invention relates to a signal reception method for receiving the signal transmitted in the fourth embodiment. This embodiment is substantially the same as the second embodiment except that the receiver side de-interleaves the received signal according to all possible interleaving modes of the transmitter side, that is, de-interleaves the received signal with the 2^{m} de-interleaving modes, and then derives all the information for transmission of the transmitter side in accordance with the optimum signal sequence resulting from de-interleaving and corresponding interleaving mode in the second embodiment; while the receiver side descrambles the received signal according to all possible scrambling modes of the transmitter side, that is, de-interleaves the received signal with 2^{m} descrambling modes, and then derives all the information for transmission of the transmitter side in accordance with the optimum signal sequence resulting from descrambling and the corresponding scrambling mode in this embodiment.

Specifically as illustrated in FIG. 13, since the transmitter side may scramble the transmission information borne in the physical resource in any of the 2^{m} scrambling modes, the receiver side needs to descramble the received signal with all possible scrambling mode of the transmitter side, that is, de-interleave the received signal with 2^{m} descrambling modes.

Then, the receiver side correlates respective signal sequences resulting from descrambling with respective candidate orthogonal codes, selects the optimum signal sequence there from by correlation results, and derives all the information for transmission of the transmitter side in accordance with the optimum signal sequence and the scrambling mode corresponding to the optimum signal sequence.

Since the transmitter side transmits the m-bit part in the information for transmission from the selected scrambling mode in the fourth embodiment, the receiver side can also derive all the information for transmission of the transmitter side properly by deriving the m-bit part in the information for transmission with the scrambling mode corresponding to the optimum signal sequence in this embodiment.

A sixth embodiment of the invention relates to a signal reception method for receiving the signal transmitted in the fourth embodiment and is substantially the same as the fifth embodiment except that the fifth embodiment adopts non-coherent detection and this embodiment adopts coherent detection.

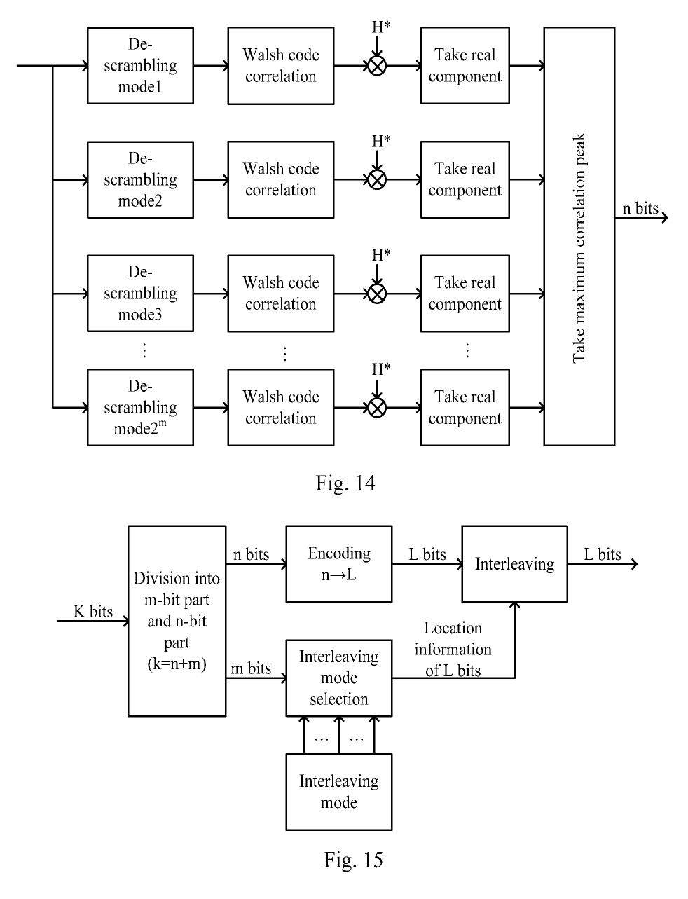

Specifically, as illustrated in FIG. 14, the receiver side derives a channel parameter H from a pilot signal, processes values of the 2^{m}*2ⁿ correlation peaks by the conjugation H* of the channel parameter H, and selects the n-bit information corresponding to the maximum correlation peak as an output, and the n-bit information is the optimum sequence. Both the process that the 2^{m}*2ⁿ correlation peaks is processed with H and the process that the maximum correlation peak is derived can employ the coherent detection in the conventional art.

A seventh embodiment of the invention relates to a signal transmission method and is substantially the same as the first embodiment except for the encoding mode adopted for the n-bit part. In the first embodiment, the transmitter side divides the k-bit information of the signal for transmission into an m-bit part and an n-bit part and then maps the n-bit information into a Walsh code. While in this embodiment, the transmitter side divides k-bit information of a signal for transmission into a m-bit part and a n-bit part and then encodes the n-bit information with another encoding mode.

Specifically, as illustrated in FIG. 15, the transmitter side divides k-bit information of a signal for transmission into a m-bit part and n-bit part, the m-bit part is used for selection of corresponding one of 2^{m} interleaving modes, and the n-bit part is encoded into an L-bit encoded sequence.

Then, the sequence into which the n-bit part is encoded, i.e., the L-bit encoded sequence, is interleaved according to the selected interleaving mode and then transmitted.

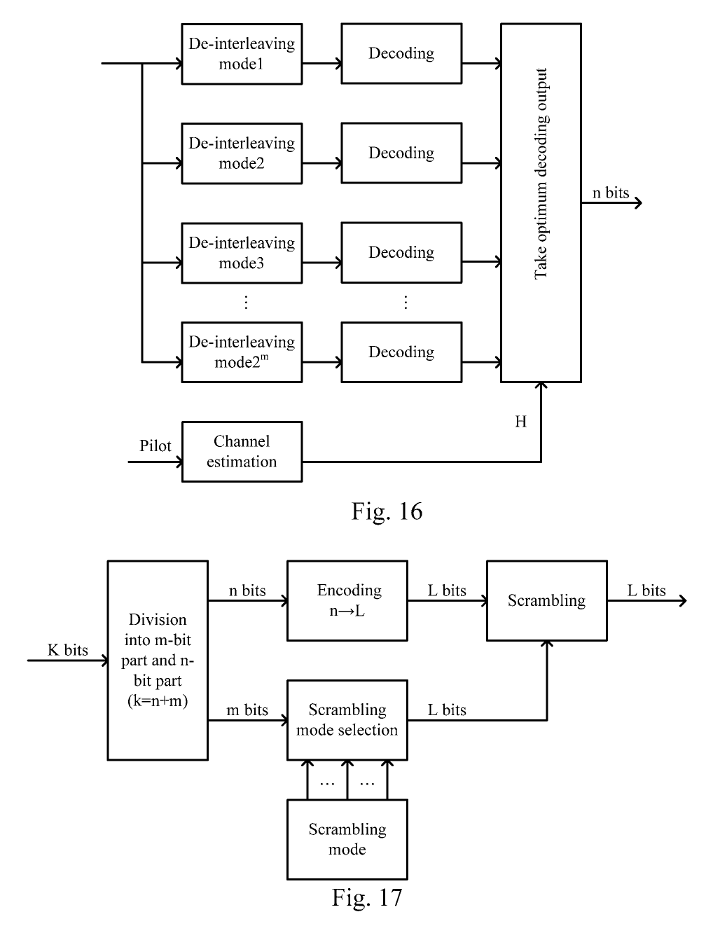

In a reception method illustrated in FIG. 16 of this embodiment, the receiver side de-interleaves the received signal. Since the transmitter side may interleave the transmission information borne in the physical resource in any of the 2^{m} interleaving modes, the receiver side needs to de-interleave the received signal all possible interleaving modes of the transmitter side, that is, de-interleave the received signal with 2^{m} de-interleaving modes to derive 2^{m} encoded sequences. Then, the receiver side decodes the 2^{m} encoded sequences, makes decisions of 2^{m} decoding outputs with reference to a channel parameter H of a pilot signal, and selects the optimum decoding output there from as the optimum signal sequence. The receiver side derives the n-bit part in the information for transmission of the transmitter side from the optimum signal sequence and the m-bit part in the information for transmission of the transmitter side according to the interleaving mode corresponding to the optimum signal sequence to thereby derive all the information for transmission of the transmitter side. Alternatively, the receiver side can perform reception by non-coherent detection.

An eighth embodiment of the invention relates to a signal transmission method and is substantially the same as the seventh embodiment except that the transmitter side selects one of the 2^{m} interleaving modes in accordance with the m-bit part and interleaves and then transmits the L-bit encoded sequence with the selected interleaving mode in the seventh embodiment. While in this embodiment, the transmitter side selects one of 2^{m} scrambling modes in accordance with the m-bit part and scrambles and then transmits the L-bit encoded sequence with the selected scrambling mode.

Specifically as illustrated in FIG. 17, the transmitter side divides k-bit information of a signal for transmission into an m-bit part and an n-bit part, the m-bit part is used for selecting a corresponding scrambling mode from the 2^{m} scrambling modes, and the n-bit part is encoded into an L-bit encoded sequence.

Then, the sequence into which the n-bit part is encoded, i.e., the L-bit encoded sequence, is scrambled with the selected scrambling mode and then transmitted.

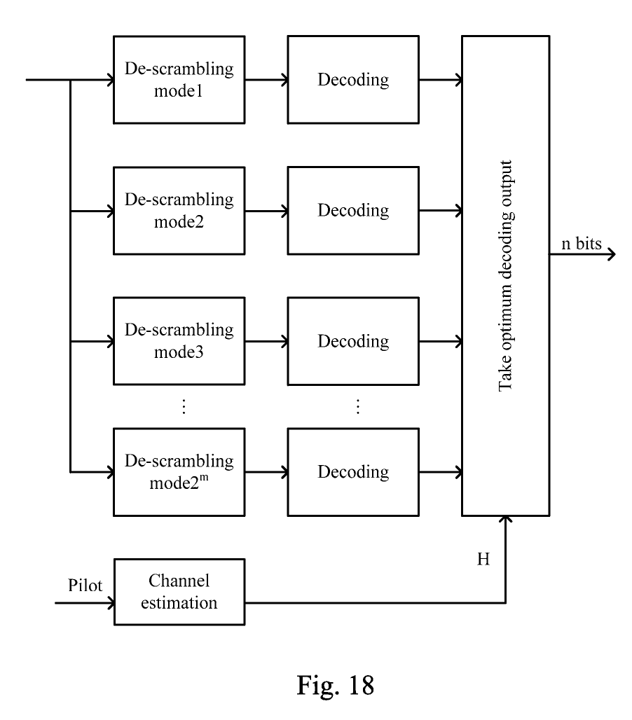

In a reception method illustrated in FIG. 18 of this embodiment, the receiver side descrambles the received signal. Since the transmitter side may scramble the transmission information borne in the physical resource in any of the 2^{m} scrambling modes, the receiver side needs to descramble the received signal with all possible scrambling modes of the transmitter side, that is, de-interleave the received signal with all 2^{m} descrambling modes to derive 2^{m} descrambled sequences. Then, the receiver side decodes the 2^{m} descrambled sequences, makes decisions of 2^{m} decoding outputs with reference to a channel parameter H of a pilot signal, and selects the optimum decoding output there from as the optimum signal sequence. The receiver side derives the n-bit part in the information for transmission of the transmitter side from the optimum signal sequence and the m-bit part in the information for transmission of the transmitter side from the scrambling mode corresponding to the optimum signal sequence to thereby derive all the information for transmission of the transmitter side. Alternatively, the receiver side can perform reception by non-coherent detection.

A ninth embodiment of the invention relates to a signal transmission method and is substantially the same as the first embodiment except that, in the first embodiment, information for transmission of the transmitter side is of a length larger than a predetermined value, the predetermined value being a length of transmission information that can be borne in a physical resource block for information transmission. For example, 8-bit information can be borne in a physical resource block and the information for transmission of the transmitter side is of a length larger than 8 bits. While in this embodiment, information for transmitting the transmitter side is of a length larger than or smaller than or equal to a predetermined value.

Therefore, for a channel over which information for transmission is larger than a predetermined value, the transmitter side divides information over the channel into an n-bit part and an m-bit part, the n-bit part is taken as information borne in a physical resource and an interleaving mode is selected for the n-bit part according to the m-bit part. For a channel over which information for transmission is smaller than or equal to a predetermined value, the transmitter side takes all information for transmission over the channel as information borne in the physical resource.

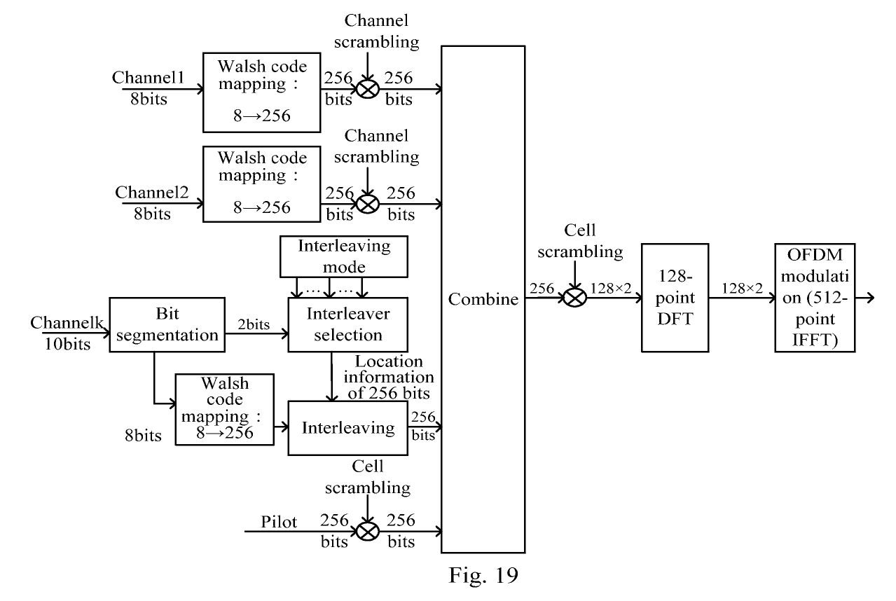

For example, as illustrated in FIG. 19, 8-bit information can be borne in a physical resource block. Information for transmission over a channel 1 and that for transmission over a channel 2 is both of 8 bits which is equal to what can be borne in the physical resource block, and information for transmission over a channel k is of 10 bits which is larger than what can be borne in the physical resource block. Therefore, the transmitter side performs transmission over each of the channels 1 and 2 as in the conventional art by taking the 8-bit information for transmission over the channel as information borne in a physical resource. The transmitter side divides the information for transmission over the channel k into an n-bit part and m-bit part, and the n bits and m bits are 8 bits and 2 bits respectively. The n-bit part (the 8-bit part) is taken as information borne in a physical resource and an interleaving mode is selected for the n-bit part according to the m-bit part (the 2-bit part). As illustrated in FIG. 19, the transmitter side can directly combine a transmission sequence resulting from interleaving with a signal over another channel or can firstly scramble the interleaved signal over the channel and then combine the signal with a signal over another channel.

Correspondingly, the receiver side derives the information for transmission of the transmitter side from the received information as in the conventional art for the channels 1 and 2; and derives part of information for transmission of the transmitter side from the optimal signal sequence resulting from de-interleaving and remaining part of information for transmission of the transmitter side from the interleaving mode corresponding to the optimal signal sequence.

As can be seen, transmissions method according to the solutions of the invention can be adopted for a channel over which information for transmission is larger than a predetermined value, and transmission can be performed as in the conventional art for a channel over which information for transmission is smaller than or equal to a predetermined value, so that the invented solutions can be well compatible with the conventional art.

A tenth embodiment of the invention relates to a signal transmission method for use in a communication system which requires a check-encoding for transmitted information.

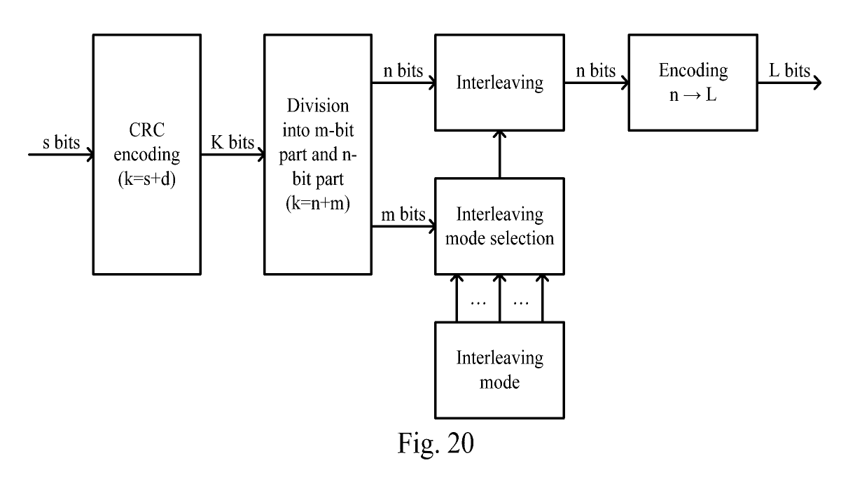

Specifically, as illustrated in FIG. 20, the transmitter side firstly check-encodes, for example, CRC-encodes information for transmission, and divides the check-encoded k-bit information into a n-bit part and a m-bit part.

Then, the transmitter side selects an interleaving mode in accordance with the m-bit part and directly interleaves the n-bit part resulting from division with the selected interleaving mode.

Finally, the transmitter side encodes an n-bit signal sequence resulting from interleaving into an L-bit signal sequence for transmission in an orthogonal code mapping or another encoding mode. In FIG. 20, the transmitter side encodes and then transmits the signal sequence resulting from interleaving to the receiver side, and the encoded information is of L bits in length.

An eleventh embodiment of the invention relates to a signal reception method for receiving the signal transmitted in the tenth embodiment.

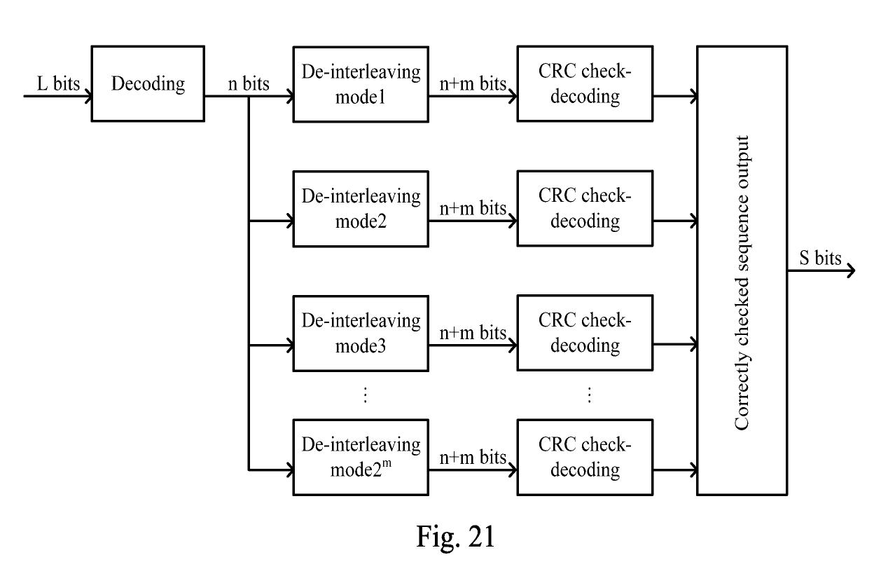

Taking the transmitted signal of the transmitter side illustrated in FIG. 20 as an example, a process of receiving the signal can be as illustrated in FIG. 21 where the receiver side decodes the received L-bit signal and de-interleaves the encoded n-bit signal. Since the transmitter side may interleave the transmission information borne in the physical resource in any of the 2^{m} interleaving modes, the receiver side needs to de-interleave the received signal with all possible interleaving modes of the transmitter side, that is, de-interleave the encoded signal into 2^{m} n-bit signal sequences with all 2^{m} de-interleaving modes.

Then, the receiver side derives all possible candidate information sequences for transmission of the transmitter side from all signal sequences resulting from de-interleaving and their corresponding interleaving modes, i.e., 2^{m} (n+m)-bit signal sequences.

The receiver side checks the respective candidate sequences and derives a candidate sequence which passes the check and is the check-encoded information for transmission of the transmitter side. Thus, the receiver side check-decodes the sequence and then derives the information for transmission of the transmitter side.

As can be seen, the receiver side only needs to decode for one time, then perform 2^{m} de-interleaving, derive the respective candidate sequences from the signal sequences resulting from de-interleaving and their corresponding interleaving modes, check the derived candidate sequences, and check-decode the sequence which passes the check to obtain the information for transmission at the transmitter side. Thus, the computing complexity at the receiver side is further reduced.

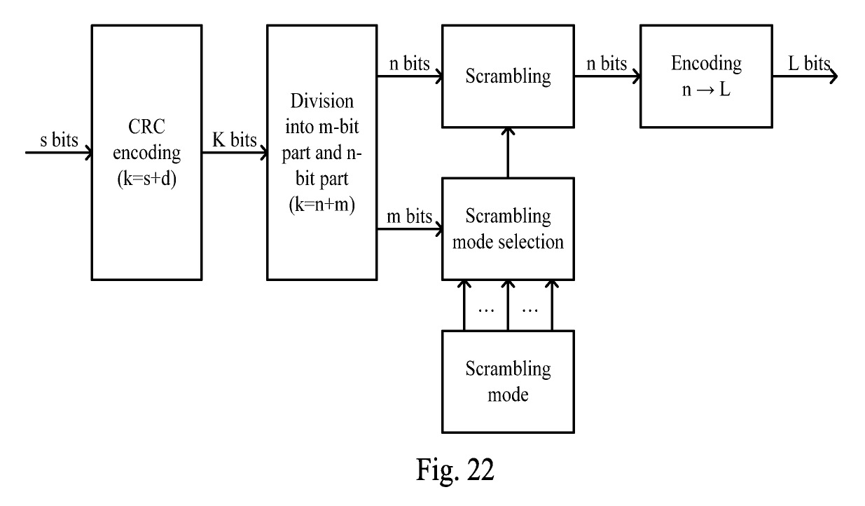

The twelfth embodiment of the invention relates to a signal transmission method and is substantially the same as the tenth embodiment except that, the transmitter side selects one of the 2^{m} interleaving modes according to the m-bit part and interleaves the n-bit part of the check-encoded information sequence according to the selected interleaving mode in the tenth embodiment. While in this embodiment, the transmitter side selects one of 2^{m} scrambling modes in accordance with the m-bit part and scrambles the n-bit part of the check-encoded information sequence according to the selected scrambling mode, as illustrated in FIG. 22.

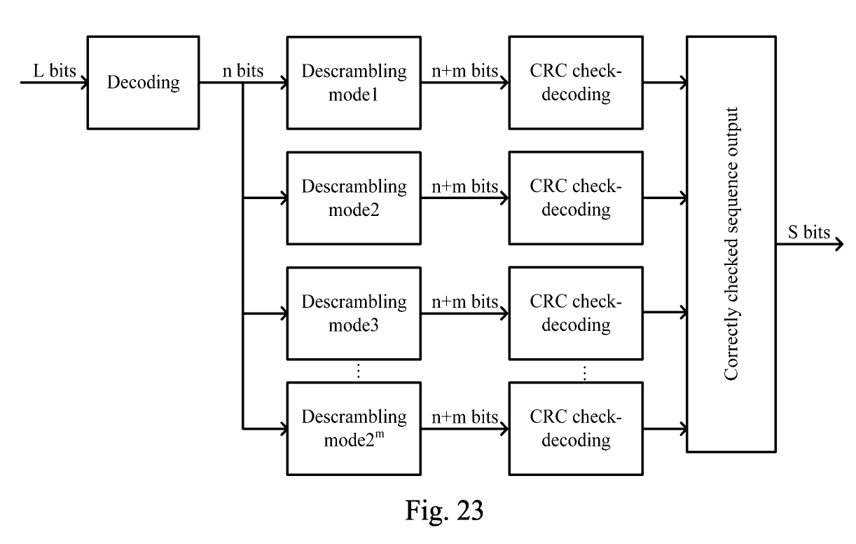

A thirteenth embodiment of the invention relates to a signal reception method for receiving the signal transmitted in the twelfth embodiment and is substantially the same as the eleventh embodiment except that, the receiver side de-interleaves the decoded signal according to all possible interleaving modes of the transmitter side in the eleventh embodiment. While in this embodiment, the receiver side descrambles the decoded signal according to all possible scrambling modes of the transmitter side, as illustrated in FIG. 23.

Those ordinarily skilled in the art can appreciate that all or part of the steps in the above method embodiments can be implemented by a program instructing relevant hardware, and the program can be stored in a computer readable storage medium, such as a read-only memory, a random memory, a magnetic disk, and an optical disk, etc., and the program can implement all or part of the steps in the above method embodiments when being executed.

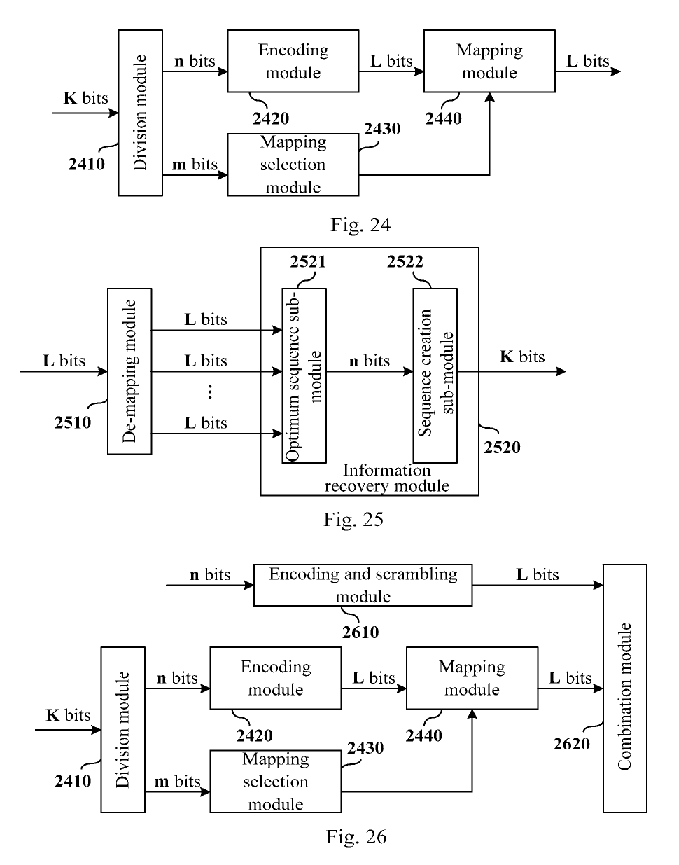

A fourteenth embodiment of the invention relates to a signal transmission device which may be structured as illustrated in FIG. 24. The signal transmission device includes a division module 2410 adapted to divide information for transmission into an n-bit part and m-bit part, the n-bit part is taken as information borne in a physical resource; an encoding module 2420 adapted to encode the n-bit part; a mapping selection module 2430 adapted to select a corresponding mapping mode according to the m-bit part; and a mapping module 2440 adapted to map the information borne in the physical resource according to the selected mapping mode and then transmit an information sequence resulting from encoding of the n-bit part.

Particularly, the mapping selection module 2430 can be an interleaving selection module, a scrambling selection module or a selection module in another mapping mode, adapted to select an interleaving mode, scrambling mode or other mapping modes in correspondence with the m-bit part respectively. Correspondingly, the mapping module 2440 can be an interleaving module, a scrambling module or another mapping module, adapted to interleave, scramble or map the sequence resulting from encoding of the n-bit part with the interleaving, scrambling or the other mapping mode selected in accordance with the m-bit part. The encoding module 2420 can be an orthogonal code mapping module, adapted to map the n-bit part into an orthogonal code, and output the mapped orthogonal code to the mapping module 2440. The orthogonal code may be a Walsh code.

This embodiment transmits part of the information for transmission of the transmitter side by mapping the information borne in the physical resource, so that more information can be transmitted in a fixed resource block. Therefore, a utilization ratio of the resource is improved significantly without degrading performance of the system.

A fifteenth embodiment of the invention relates to a signal reception device for receiving the transmission signal in the fourteenth embodiment. The signal reception device includes a de-mapping module 2510 adapted to de-map the received signal in all possible mapping modes of the transmission device; and an information recovery module 2520 adapted to derive information for transmission over the present channel from the optimum signal sequence resulting from de-mapping and its corresponding mapping mode. The information recovery module 2520 includes an optimum sequence sub-module 2521 adapted to decode respective signal sequences resulting from de-mapping and to select the optimum signal sequence there from; and a sequence creation sub-module 2522 adapted to derive part of the information for transmission of the transmission device from the optimum signal sequence output from the optimum sequence sub-module 2521 and remaining part of the information for transmission of the transmission device from the mapping mode corresponding to the optimum signal sequence, and combine them into the information for transmission over the channel.

Particularly, the de-mapping module 2510 can be a de-interleaving module or a descrambling module, adapted to de-interleave or descramble the received signal with all possible interleaving modes or scrambling modes of the transmitter side respectively. The optimum sequence sub-module 2521 can be an orthogonal correlation sub-module, adapted to correlate the respective signal sequences resulting from de-mapping with respective candidate orthogonal codes and select a sequence with the maximum correlation peak from respective correlation results as the optimum signal sequence.

A sixteenth embodiment of the invention relates to a signal transmission device and is substantially the same as the fourteenth embodiment except that information for transmission of the transmission device is of a length larger than a predetermined value in the fourteenth embodiment, the predetermined value being a length of transmission information that can be borne in a physical resource block for information transmission. For example, 8-bit information can be borne in a physical resource block and information for transmission of the transmission device is of a length larger than 8 bits. While in this embodiment, the transmission device has both information with a length larger than the predetermined value for transmission over at least one channel and information with a length smaller than or equal to the predetermined value for transmission over another or other channels.

Therefore, the transmission device in this embodiment is structured as illustrated in FIG. 26. Compared with the transmission device in the fourteenth embodiment, the following modules are added: an encoding and scrambling module 2610 adapted to encode information with a length no less than a predetermined value for transmission over a channel, and scramble an encoding output into a transmission sequence over the channel with scrambling code of the channel; and a combination module 2620 adapted to combine and then transmit the transmission sequences over the respective channels.

For a channel, over which information is transmitted, is of a length larger than the predetermined value, the information after being processed by the division module 2410, the encoding module 2420, the mapping selection module 2430 and the mapping module 2440 as in the fourteenth embodiment can be output from the mapping module 2440 directly to the combination module 2620 for combination with a transmission sequence over another channel as illustrated in FIG. 26, or can be output from the mapping module 2440 to the channel scrambling module, and the channel scrambling module scrambles the information with the scrambling code of the channel and then outputs the information to the combination module 2620.

This embodiment can be well compatible with the conventional art.

A seventeenth embodiment of the invention relates to a signal reception device for receiving the transmission signal in the sixth embodiment and is substantially the same as the fifth embodiment except that, this embodiment further includes a signal reception module adapted to receive a signal over a channel, over which information transmitted is of a length less than or equal to the predetermined value, and derive the information for transmission of the transmitter side from the received information, in addition to the modules of the reception device in the fifth embodiment.

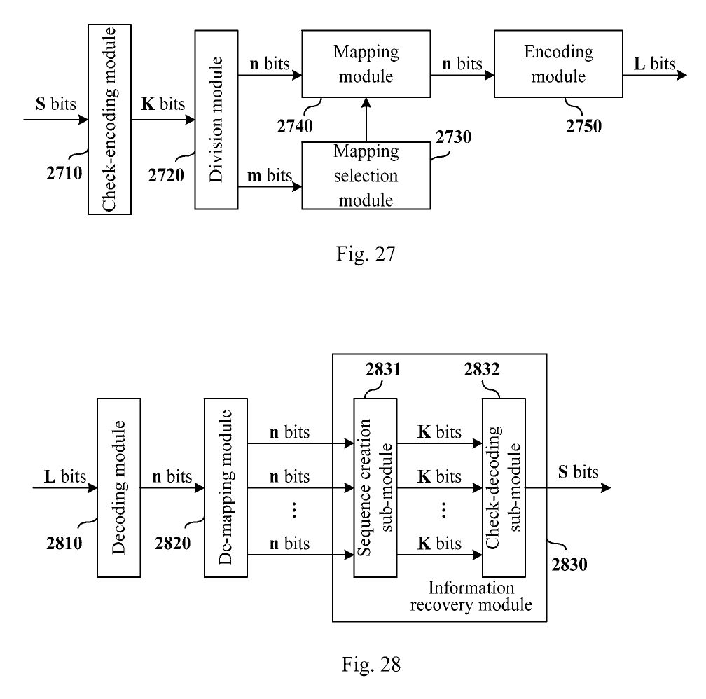

An eighteenth embodiment of the invention relates to a signal transmission device structured as illustrated in FIG. 27. The signal transmission device includes a check-encoding module 2710 adapted to check-encode a S-bit information frame over the channel into a K-bit sequence of information for transmission; a division module 2720 adapted to divide the information for transmission into a n-bit and a m-bit by dividing the check-encoded information and the n-bit part is taken as information borne in a physical resource; a mapping selection module 2730 adapted to select a corresponding mapping mode in accordance with the m-bit part; a mapping module 2740 adapted to map the n-bit part output from the division module 2720 according to the selected mapping mode; and an encoding module 2750 adapted to encode and then transmit an information sequence output from the mapping module 2740.

Particularly, the mapping selection module 2730 can be an interleaving selection module, a scrambling selection module or a selection module in another mapping mode, adapted to select an interleaving, scrambling or other mapping modes in correspondence with the m-bit part respectively; and correspondingly, the mapping module 2740 can be an interleaving module, a scrambling module or another mapping module, adapted to interleave, scramble or map the n-bit part with the interleaving, scrambling or the other mapping modes selected in accordance with the m-bit part.

A nineteenth embodiment of the invention relates to a signal reception device for receiving the transmission signal in the eighteenth embodiment. The signal reception device includes a decoding module 2810 adapted to decode the received signal; a de-mapping module 2820 adapted to de-map the decoded signal with all possible mapping mode of the transmitter side; and an information recovery module 2830 adapted to derive information for transmission over the present channel from the optimum signal sequence resulting from de-mapping and its corresponding mapping mode. The information recovery module 2830 includes a sequence creation sub-module 2831 adapted to combine the n-bit information resulting from de-mapping output from the de-mapping module 2820 with the m-bit information corresponding to de-mapping modes adopted to derive the signal into (n+m)-bit candidate sequences; and a check-decoding sub-module 2832 adapted to check-decode the respective candidate sequences, and select the optimum signal sequence from check-decoding results as the information for transmission over the channel.

Particularly, the de-mapping module 2820 can be a de-interleaving module or a descrambling module, adapted to de-interleave or descramble the sequence resulting from decoding according to all possible interleaving modes or scrambling modes of the transmitter side respectively.

As can be seen, the reception device can derive the information for transmission of the transmitter side simply by decoding for one time, performing 2^{m} de-mappings, deriving the candidate sequences from the signal sequences resulting from de-mapping and their corresponding mapping modes, checking the derived candidate sequences, and check-decoding the sequence which passes the check to further reduce complexity of operations at the receiver side.

In the embodiments of the invention, the transmitter side divides information for transmission into a m-bit part and a n-bit part. The n-bit part is taken as information borne in a physical resource. A mapping mode is selected based on the m-bit part and the information borne in the physical resource is mapped with the selected mapping mode and then transmitted. At the receiver side, the received signal is de-mapped with all possible mapping modes of the transmitter side, and the information for transmission of the transmitter side is derived from the optimum signal sequence resulting from de-mapping and its corresponding mapping mode. Therefore, more information can be transmitted with a fixed resource block and a utilization ratio of the resource is improved significantly without degrading performance of the system.

Although the invention has been illustrated and described with reference to some preferred embodiments thereof, those ordinarily skilled in the art shall appreciate various variations can be made to the invention without departing from the spirit and scope of the invention.

What is claimed is:

1. A signal transmission method, comprising:
dividing information for transmission into an n-bit part and an m-bit part, the n-bit part being taken as information borne in a physical resource; and
mapping a sequence carrying the n-bit part with a mapping mode corresponding to the m-bit part and then transmitting the sequence.

2. The signal transmission method according to claim 1, wherein the sequence carrying the n-bit part is resulting from encoding of the n-bit part.

3. The signal transmission method according to claim 2, wherein the encoding comprises mapping the n-bit part into an orthogonal code.

4. The signal transmission method according to claim 1, wherein:
the information borne in the physical resource for information transmission has a length of n bits, and wherein
for a channel, over which another information is transmitted, the another information for transmission over the channel is taken as the information borne in the physical resource, the another information having a length smaller than or equal to n bits.

5. The signal transmission method according to claim 1, wherein:
the sequence carrying the n-bit part is the n-bit part, and the information for transmission is (n+m)-bit information resulting from check-encoding an information frame for transmission; and
after mapping the sequence carrying the n-bit part, the method further comprises: encoding a mapping result.

6. A signal reception method, comprising:
de-mapping a sequence carrying a received signal and
deriving transmitted information from an optimum signal sequence resulting from the de-mapping and a corresponding mapping mode.

7. The signal reception method according to claim 6, wherein the deriving of the transmitted information from the optimum signal sequence comprises:
decoding respective sequences resulting from the de-mapping, and selecting the optimum signal sequence from decoding results; and
combining the optimum signal sequence and an information sequence corresponding to a mapping mode of the optimum signal sequence into the transmitted information.

8. The signal reception method according to claim 7, wherein:
the decoding respective sequences comprises: correlating the respective sequences with respective candidate orthogonal codes; and
the selecting the optimum signal sequence from the decoding results comprises: selecting a sequence with a maximum correlation peak from the correlation results as the optimum signal sequence.

9. The signal reception method according to claim 7, wherein the selecting the optimum signal sequence from the decoding results comprises:
deriving a channel parameter from a pilot signal; and
performing a coherent detection on the decoding results according to the channel parameter, and selecting the optimum signal sequence from the detection results.

10. The signal reception method according to claim 6, wherein:
the sequence carrying the received signal is a sequence resulting from decoding of the received signal; and
the deriving the transmitted information from the optimum signal sequence resulting from de-mapping and a corresponding mapping mode comprises: check-decoding respective candidate sequences, and selecting the optimum signal sequence from check-decoding results as the transmitted information.

11. The signal reception method according to claim 10, wherein the selecting the optimum signal sequence comprises:
deriving a channel parameter from a pilot signal; and
performing a coherent detection on the check-decoding results according to the channel parameter, and selecting the optimum signal sequence from the detection results.

12. A signal transmission device, comprising:
a division module, adapted to divide information for transmission into an n-bit part and an m-bit part, the n-bit part being taken as information borne in a physical resource;
a mapping selection module, adapted to select a corresponding mapping mode in accordance with the m-bit part; and
a mapping module, adapted to map a sequence carrying the n-bit part with a mapping mode corresponding to the m-bit part and then transmit the sequence.

13. The signal transmission device according to claim 12, further comprising: an encoding module, adapted to encode the n-bit part output from the division module into the sequence carrying the n-bit part.

14. The signal transmission device according to claim 13, wherein the encoding module is an orthogonal code mapping module adapted to map the n-bit part into a corresponding orthogonal code as the sequence carrying the n-bit part.

15. The signal transmission device according to claim 12, wherein the information borne in the physical resource for information transmission has a length of n bits;
the device further comprises:
an encoding and scrambling module adapted to encode additional information for transmission over a channel, scramble an encoding result with a scrambling code of the channel, and then output, wherein the additional information has a length smaller than or equal to n bits; and
a combination module, adapted to combine and then transmit the sequence from the encoding and scrambling module and the sequence from the mapping module.

16. The signal transmission device according to claim 15, further comprising: a channel scrambling module, connected between the mapping module and the combination module, and adapted to scramble the sequence output from the mapping module with the scrambling code of the channel and then output the sequence to the combination module.

17. The signal transmission device according to claim 12, further comprising:
a check-encoding module, adapted to check-encode an information frame into (n+m)-bit information for transmission; and
an encoding module, adapted to encode and then output the sequence output from the mapping module.

18. A signal reception device, comprising:
a de-mapping module, adapted to de-map a sequence carrying a received signal according to all possible mapping modes of the received signal; and
an information recovery module, adapted to derive transmitted information from an optimum signal sequence resulting from de-mapping and corresponding mapping mode.

19. The signal reception device according to claim 18, wherein the information recovery module comprises:
an optimum sequence sub-module, adapted to decode respective sequences resulting from the de-mapping, and select the optimum signal sequence from decoding results; and
a sequence creation sub-module, adapted to combine the optimum signal sequence and an information sequence corresponding to a mapping mode of the optimum signal sequence into the transmitted information.

20. The signal reception device according to claim 19, wherein the optimum sequence sub-module is an orthogonal code correlation sub-module, adapted to correlate the respective sequences resulting from the de-mapping with respective candidate orthogonal codes, and select a sequence with a maximum correlation peak from all correlation results as the optimum signal sequence.

21. The signal reception device according to claim 18, further comprising a decoding module, adapted to decode the received signal into the sequence carrying the received signal;
wherein the information recovery module comprises:
a sequence creation sub-module, adapted to combine respective sequences resulting from de-mapping and respective sequences corresponding to mapping modes into respective candidate sequences; and
a check-decoding sub-module, adapted to check-decode the respective candidate sequences, and select the optimum signal sequence from check-decoding results as the transmitted information.
